(19) United States
(12) Patent Application Publication
(10) Pub. No.: US 2024/0185430 A1
(43) Pub. Date: Jun. 6, 2024

(54) BRAIN IMAGE SEGMENTATION USING TRAINED CONVOLUTIONAL NEURAL NETWORKS

(71) Applicant: Owl Navigation, Inc., Plymouth, MN (US)

(72) Inventors: Dan Askarov, Minnetonka, MN (US); Alan Lund, Eden Prairie, MN (US); Guillermo Sapiro, Durham, NC (US); Noam Harel, Minnetonka, MN (US)

(21) Appl. No.: 18/282,695

(22) PCT Filed: Mar. 18, 2022
(86) PCT No.: PCT/US2022/020895

§ 371 Date: Sep. 18, 2023

Related U.S. Application Data
(60) Provisional application No. 63/212,957, filed on Jun. 21, 2021.
(60) Provisional application No. 63/163,507, filed on Mar. 19, 2021.

(51) Int. Cl. G06T 7/174; G06T 7/00; G06T 7/11; G06T 7/149

(52) U.S. Cl. CPC G06T 7/174; G06T 7/0014; G06T 7/11; G06T 7/149; G06T 2207/10096; G06T 2207/10144; G06T 2207/20016; G06T 2207/20081; G06T 2207/20084; G06T 2207/30008; G06T 2207/30168

(57) ABSTRACT

Disclosed embodiments include methods and computer systems for brain image prediction or segmentation. A clinical image file of data representative of a patients' brain image, including structures of interest (SOI) such as the subthalamic nucleus (STN), is applied to and processed by a segmentation process. The segmentation process uses one or more machine learning approaches such as trained deep learning models to identify the SOI in the clinical image. Output by the segmentation process is a segmented image file of data representing the brain image in which the structures of interest (SOI) are segmented. By the segmentation process, the SOI in clinical image, including the locations, orientations and/or boundaries of the SOI, are accurately predicted or identified, and can thereby be presented in an enhanced visualization form (e.g., highlighted) in the segmented image.

### CROSS-REFERENCE TO RELATED APPLICATION

This application is a national phase application of PCT Application No. PCT/US2022/020895, internationally filed on Mach 18, 2022, which claims the benefit of Provisional Application No. 63/163,507, filed Mar. 19, 2021, and also claims the benefit of Provisional Application No. 63/212,957, filed Jun. 21, 2021, which are all incorporated herein by reference in their entireties for all purposes.

### FIELD

This disclosure relates generally to the use of machine learning-based methods and apparatus for predicting or segmenting regions of interest in medical images. Disclosed embodiments include methods for training deep learning models that can be used to segment structures in brain images.

### BACKGROUND

Prediction or segmentation involves identifying regions of interest in images. The accurate segmentation of structures or other regions of interest in patients' medical images can enhance clinical outcomes of procedures using those images. For example, deep brain stimulation (DBS) therapy has shown clinical efficacy in the mediation of symptomatic motoric behavior associated with Parkinson's disease, essential tremor, dystonia, and other conditions. DBS therapy makes use of electrodes inserted into certain target regions of interest in the patient's brain, such as the subthalamic nucleus (STN), internal segment of the globus pallidus (GPi), and/or the external segment of the globus pallidus (GPe). Images of the patient's brain, such as those produced using magnetic resonance imaging (MRI) scanners, are commonly used by clinicians to guide and accurately place the electrodes. The precise identification of these target regions of interest in the images can enhance the accuracy of the electrode placement and the efficacy of the therapy.

Automated processes for segmenting brain images offer certain advantages. They can, for example, streamline clinical workflow, eliminate human bias associated with the segmentation process, and provide consistent results. The use of machine learning processes, such as deep-learning, including the use of convolutional neural networks (CNNs) for purposes of image analysis and computer vision are generally known and disclosed, for example, in the following articles: Krizhevsky et al., ImageNet classification with deep convolutional neural networks, http://code.google.com/p/cuda-convnet/; and Lecun et al., Deep Learning, Nature, vol. 521, issue 7553, pp. 436-444. Methods and systems for generating images of patient's brains are disclosed in the Sapiro U.S. Pat. No. 9,600,778.

Standard clinical images are generated at many health care facilities by MRI scanners operating at 1.5 Tesla and 3 Tesla (i.e., 1.5 T and 3 T) field strengths. Unfortunately, it may be difficult to clearly visualize regions of interest such as the STN, GPi and GPe in clinical images taken using these 1.5 T and 3 T MRI scanners. Although MRI scanners operating at higher field strengths, such as 7 T, are known and can produce higher contrast resolution images than those of 1.5 T and 3 T scanners and that may enhance the ability of users to visualize and distinguish between adjacent structures or regions, these higher field strength scanners are not widely available for clinical applications.

There remains a need for improved methods and apparatus for accurately segmenting regions of interest in medical images. In particular, there is a need for improved methods for segmenting regions of interest in clinical images produced using commonly available MRI scanners such as 1.5 T and 3 T scanners. Efficacy of therapy guided by these clinical images, such as DBS electrode placement, may be enhanced by such methods and apparatus.

### SUMMARY

One example relates to a ground truth image generation method. Embodiments include a method for generating image file pairs usable to train deep learning models, comprising: receiving access to a first image file of a three-dimensional body portion of a subject including structures of interest (SOI), wherein the first image file is defined by a first coordinate space and a first effective resolution such as a contrast resolution; receiving access to a second image file of the three-dimensional body portion of the subject including the SOI, wherein the second image file is defined by a second coordinate space and a second effective resolution such as a contrast resolution that is greater than the first resolution; segmenting the SOI in the second image file; transforming the segmented SOI into the first coordinate space to create a third image file of the three-dimensional body portion of the subject including the SOI; and wherein the first image file and the third image file are usable to train deep learning models for segmentation of SOI in patient images corresponding to the SOI in the first image file and the third image file.

In embodiments, receiving access to the first image file includes receiving access to a first image file produced by a scanner defined by a field strength less than or equal to about three Tesla. In any or all of the above embodiments, receiving access to the second image file includes receiving access to a second image file produced by a scanner defined by a field strength greater than or equal to about five Tesla. In any or all of the above embodiments, receiving access to the second image file includes receiving access to a second image file produced by a scanner defined by a field strength greater than or equal to about seven Tesla. In any or all of the above embodiments, receiving the first image file includes receiving a first image file produced by a first scanner; and receiving the second image file includes receiving a second image file produced by a second scanner different than the first scanner.

In any or all of the above embodiments, the three dimensional body portion includes a head of the subject. In any or all of the above embodiments, the SOI includes one or more of a subthalamic nucleus, globus pallidus, red nucleus, substantia nigra, thalamus or caudate nucleus.

In any or all of the above embodiments, segmenting the SOI in the second image includes manually segmenting the SOI. In any or all of the above embodiments, transforming the SOI includes affine transforming the SOI. In any or all of the above embodiments, transforming the SOI includes transforming the SOI to an accuracy of less than or equal to about one voxel. In any or all of the above embodiments, transforming the SOI includes transforming the SOI to an accuracy of less than or equal to about 1 mm. In any or all of the above embodiments, transforming the SOI includes electronically transforming the SOI.

Any or all of the above embodiments may further include quality checking the SOI in the third image file. In any or all of the above embodiments, quality checking the SOI includes: transforming the first image file into the second coordinate space to produce a fourth image file; transforming the third image file into the second coordinate space to produce a fifth image file; and comparing the SOI in fourth image file and the fifth image file. Comparing SOI in the fourth image file and the fifth image file may include a manual visualization.

In any or all of the above embodiments, segmenting the SOI comprises segmenting a region of interest including the SOI, wherein the region of interest comprises a portion of the body portion defined by the second image file.

Embodiments include a computer system operable to provide any or all of the functionality of any of the ground truth image generation method embodiments described above.

Another example relates to a model training method. Embodiments include a method for training a deep learning model, comprising: receiving access to a plurality of pairs of training image files, wherein one or more of the pairs of training image files is optionally generated by any of the ground truth image generation method embodiments described above, and includes: a first image file of a three dimensional body portion of a subject including structures of interest (SOI), wherein the first image file is defined by a first coordinate system and a first effective resolution; and a second image file of the three dimensional body portion of the subject including the SOI, wherein SOI of the second image file are defined by a second effective resolution that is greater than the first resolution, and are defined to the first coordinate system; and iteratively processing the plurality of pairs of training image files by a first deep learning model to train the first deep learning model, including producing a plurality of partially-trained iterations of the first deep learning model and a first trained segmentation deep learning model optimized for segmentation of the SOI.

In any or all of the above embodiments, iteratively processing the plurality of pairs of training images includes iteratively processing the plurality of pairs of training set images by a neural network deep learning model, and optionally a convolutional neural network deep learning model.

Any or all of the above embodiments may further include validating the training of the deep learning model. Validating the training of the deep learning model may include: receiving access to a third image file of a three dimensional body portion of a subject different that the subjects of the pairs of training image files and including the SOI, wherein the third image file is defined by a third effective resolution that is less than the second resolution; receiving access to a fourth image file of the three dimensional body portion of the subject of the third image file and including the SOI, wherein the fourth image file is defined by a fourth effective resolution greater than the third resolution and the SOI is segmented; processing the third image file by each of one or more of the plurality of partially-trained iterations of the first deep learning model to produce one or more associated iteration image files including the segmented SOI; and comparing the segmented SOI in each of the one or more of the iteration image files to the segmented SOI in the fourth image file to assess a level of optimization of each of the one or more of the partially-trained iterations of the first deep learning model.

In any or all of the above embodiments, the first image file of the set of training image files was produced by a scanner defined by a field strength less than or equal to about three Tesla. In any or all of the above embodiments, the second image file of the set of training image files includes SOI produced by a scanner defined by a field strength greater than or equal to about five Tesla. In any or all of the above embodiments, the second image file of the set of training image files includes SOI produced by a scanner defined by a field strength greater than or equal to about seven Tesla. In any or all of the above embodiments, the first image file of the set of training image files includes a first image file produced by a first scanner; and the second image file of the set of training image files includes a second image file produced by a second scanner different than the first scanner.

In any or all of the above embodiments, the three dimensional body portion includes a head of the subject. In any or all of the above embodiments, the SOI includes one or more of a subthalamic nucleus, globus pallidus, red nucleus, substantia nigra, thalamus or caudate nucleus.

In any or all of the above embodiments, the second image file of the set of training image files includes the SOI defined to the first coordinate system to an accuracy of less than or equal to about one voxel. In any or all of the above embodiments, the second image file of the set of training image files includes the SOI defined to the first coordinate system to an accuracy of less than or equal to about one mm. In any or all of the above embodiments, the second image file of the set of training image files includes a region of interest of the body portion defined by the second image file, and wherein the region of interest includes the SOI and comprises a portion of the body portion defined by the second image file.

Any or all of the above embodiments may further include augmentation transforming one or both of the first image file and the second image file of set of training image files before processing the one or both of the first image file and the second image file by the first deep learning model, optionally including one or more of a canonical orientation transformation, a normalize intensity transformation, a region of interest crop size transformation, a training crop transformation, a resample transformation, or an add noise transformation.

Any or all of the above embodiments may further include iteratively processing the first image file and the second image file by one or more additional deep learning models to train each of the one or more additional deep learning models and produce one or more associated trained segmentation deep learning models optimized for segmentation of the SOI, wherein each of the one or more additional trained deep learning models is different than the first trained deep learning model and different than others of the one or more additional trained deep learning models.

Embodiments include a computer system operable to provide any or all of the functionality of embodiments of the model training method described above.

Another example relates to segmentation prediction. Embodiments include a method for segmenting structures of interest (SOI) in a patient image file, comprising: receiving access to a clinical patient image file of a three dimensional body portion including the SOI, wherein the clinical patient image file is defined by a first effective resolution; processing the patient image file by a first deep learning model trained using a plurality of pairs of training image files to produce a first segmented image file of the body portion with the SOI segmented, wherein (1) one or more of the pairs of training image files was generated by the method or using the computer system of any one or more of the ground truth image generation embodiments described above, and/or (2) the first deep learning model was trained by the method or using the computer system of any one or more of the embodiments of the model training method described above.

Embodiments may further include processing the patient image file by one or more additional deep learning models to produce one or more additional and associated segmented image files with the SOI segmented, wherein each of the one or more additional deep learning models is different than the first deep learning model and different than others of the one or more additional deep learning models.

Embodiments may further include combining the SOI of each of the first segmented image file and one or more additional segmented image files into a multiple model patient image file, wherein the step of combining is optionally performed using a voting algorithm.

In any or all of the above embodiments, the clinical patient image file was produced by a scanner defined by a field strength less than or equal to about three Tesla. In any or all of the above embodiments, the first deep learning model was trained using a set of training image files including images produced by a scanner defined by a field strength greater than or equal to about seven Tesla.

In any or all of the above embodiments, the body portion includes a head and the SOI includes one or more of a subthalamic nucleus, globus pallidus, red nucleus, substantia nigra, thalamus or caudate nucleus.

Embodiments include a computer system operable to provide any or all of the functionality of the segmentation prediction embodiments described above.

### BRIEF DESCRIPTION OF THE DRAWINGS

FIG. 1 is a diagrammatic illustration of a clinical image structures of interest (SOI) prediction or segmentation method, in accordance with embodiments.

FIG. 2 is a diagrammatic illustration of a deep learning model training method, in accordance with embodiments.

FIG. 3 is diagrammatic illustration of a method for generating pairs of training image files, in accordance with embodiments.

FIGS. 4A and 4B are diagrammatic illustrations of a region of interest (ROI) prediction or segmentation method, in accordance with embodiments.

FIG. 5 is a diagrammatic illustration of a method for generating pairs of quality check images, in accordance with embodiments.

FIG. 6 is a diagrammatic illustration of a clinical image SOI prediction or segmentation method, in accordance with embodiments.

FIG. 7 is a diagrammatic illustration of a networked computer system that can be used to implement the methods described in connection with FIGS. 1-6.

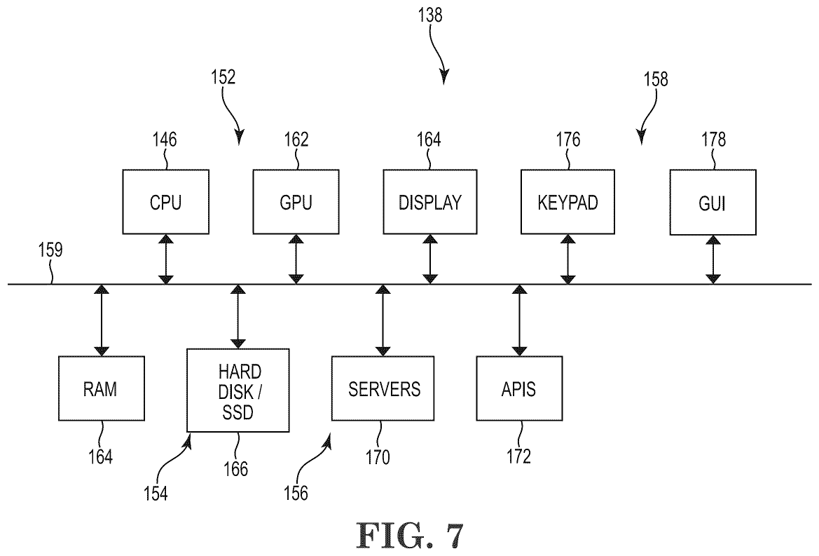

### DETAILED DESCRIPTION

### Overview

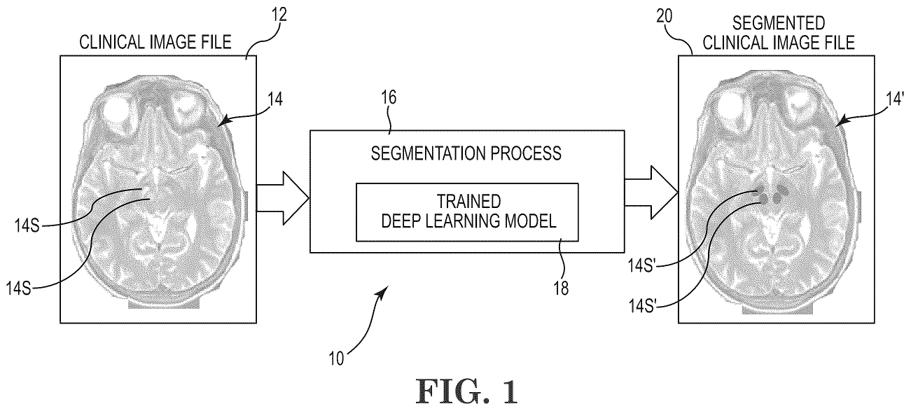

FIG. 1 is a diagrammatic illustration of a brain image prediction or segmentation method 10 in accordance with embodiments. As shown, a clinical image file 12 of data representative of an of an individual patients' brain image 14, including structures of interest (SOI) 14S such as the subthalamic nucleus (STN), internal segment of the globus pallidus (GPi), and/or external segment of the globus pallidus (GPe), is applied to and processed by a computer-implemented segmentation process 16. Segmentation process 16 uses one or more machine learning approaches such as trained deep learning models 18 to identify the SOI 14S in the clinical image 14. Output by the segmentation process 16 is a segmented image file 20 of data representing the brain image 14′ in which the structures of interest (SOI) 14S′ are segmented. By the segmentation process 16, the SOI 14S in clinical image 14, including the locations, orientations and/or boundaries of the SOI, are accurately predicted or identified, and can thereby be presented in an enhanced visualization form (e.g., highlighted) as SOI 14S′ in the segmented image 14′.

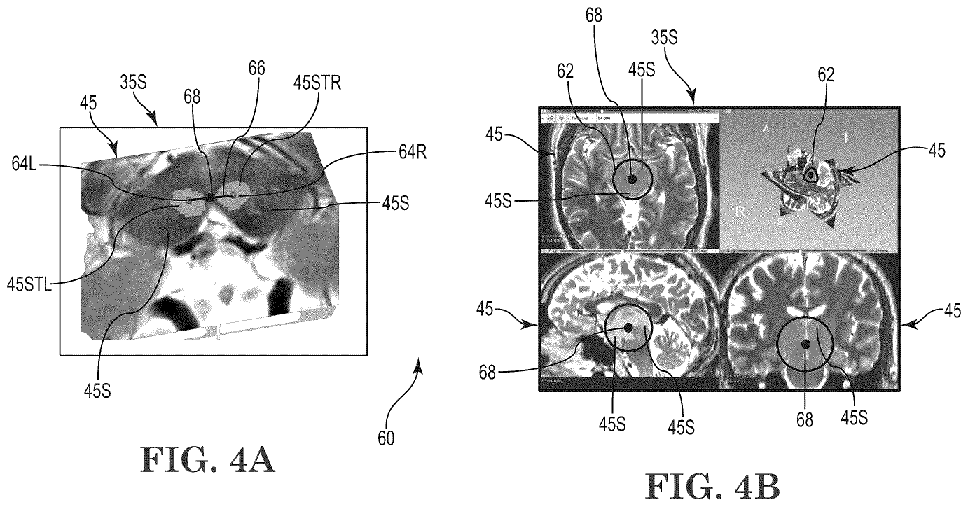

Although depicted as two dimensional for purposes of example in FIG. 1, clinical image files 12 may define three dimensional images 14 and three dimensional SOI 14S in embodiments (e.g., as shown for example in FIG. 4B. Segmented image file 20, and other image files described herein, may also define three dimensional images such as segmented image 14′. Clinical image files 12 are commonly generated at health care and other facilities by imaging systems that provide the images at a given characteristic, such as contrast resolution. Contrast resolution may generally be defined as the ability to distinguish between differences in intensity in the image. Another characteristic that may impact a user's ability to distinguish between structures or regions in an image is known as spatial resolution. Spatial resolution can be defined, for example, by specifications such as the size of the voxels (volume, or three-dimensional pixels) making up the image 14. In general, the smaller the size and the greater the number of voxels per unit area, the higher the spatial resolution of the image 14. Magnetic resonance imaging (MRI) scanners commonly used in clinical health care and other facilities operate at magnetic field strengths such as 1.5 Tesla and 3 Tesla (i.e., so-called 1.5 T and 3 T scanners). In general, the higher the magnetic field strength of the MRI scanner, the higher the contrast resolution or other resolution-related characteristics that effectively enhance the ability of a user to resolve or distinguish features of the images such as 14 that can be produced by the scanner.

In embodiments, segmentation method 10 is used to segment brain structures of interest (e.g., SOI 14S) such as the subthalamic nucleus (STN), internal segment of the globus pallidus (GPi), external segment of the globus pallidus (GPe), red nucleus (RN), substantia nigra (SN), thalamus and/or caudate nucleus. Therapies for treatment of diseases such as Parkinson's disease, dystonia and essential tremor (ET) may involve surgical procedures including the placement of electrodes into target brain structures of these types, and images may be used to guide these surgical procedures or other therapies. In general, the efficacy of the therapies may be enhanced by the accurate positioning of the electrodes in the target structures of interest. However, some or all of these brain structures may be difficult to visualize on clinical images 14 (e.g., images produced on 1.5 T or 3 T scanners). By the use of the enhanced visualization provided by method 10 and segmented brain images such as 14′, efficacy of the therapy can be enhanced. For example, as shown diagrammatically in FIG. 1, the SOI 14S′ of the segmented image 14′ have enhanced visualization, such as higher effective resolution (for example contrast resolution), than the SOI 14S in the clinical image 14.

Imaging systems such as so-called 7 T MRI scanners are generally known and are capable of producing images having effective resolutions, such as for example contrast resolutions, greater than those of certain clinical images such as 14. However, relatively high contrast resolution imaging systems of these types are less common than clinical imaging systems, and may be available for example at certain research institutions. Segmentation method 10 thereby effectively enhances the resolution of at least key portions of clinical images 14, (e.g., SOI 14S) to produce the segmented images 14′ with relatively high contrast resolution SOI 14S′, and thereby enhances the efficacy of treatments provided by images produced by relatively low contrast resolution clinical imaging systems. The segmentation method 10 can be efficiently performed at the locations of the clinical scanners, or remotely with the clinical images 14 and segmented images 14′ electronically transmitted over networks between the facilities operating the clinical imaging systems and providers of the segmentation process 18 (e.g., as software as a service (SaaS)).

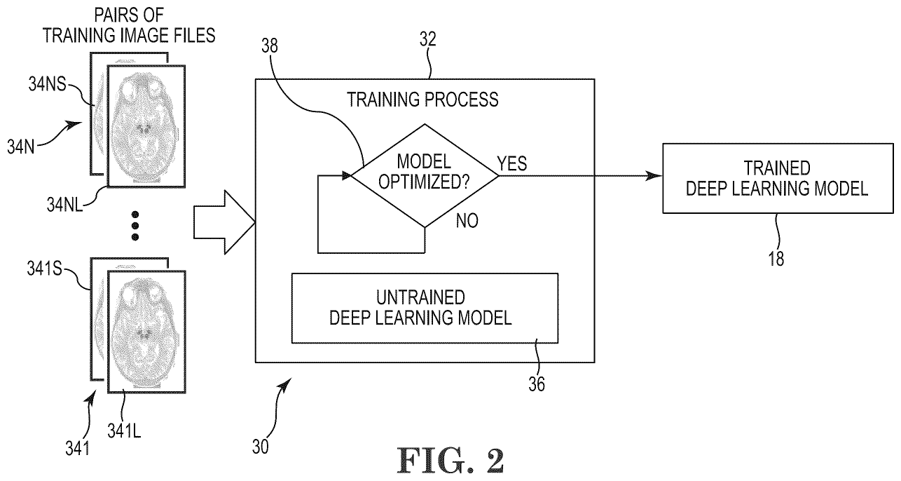

FIG. 2 is a diagrammatic illustration of a training method 30 by which the trained deep learning models 18 or other machine learning approaches may be produced. Training method 30 includes a training process 32 by which one or more sets such as pairs of training image files 34₁-34_{N} (each of which may be referred to herein as a pair of training image files 34) are applied to and processed by an untrained deep learning model 36 in an iterative process 38. The untrained deep learning models 36 are computer-implemented algorithms defining mathematical operations governed by a large number of parameters. Each pair of training image files 34₁-34_{N} includes a first or source image file 34S and an associated second or ground truth or labeled image file 34L in which the SOI in the image files are labeled or identified. Source image files 34₁S-34_{N}S and labeled image files 34₁L-34_{N}L are shown in FIG. 2 for purposes of example. During each iteration of the iterative process 38, the parameters of the deep learning model 36 are updated to “train” and better enable the model to identify and segment the structures of interest. Following a sufficient number of iterations of the iterative process 38, the model is optimized or trained and ready for use as the trained deep learning model 18 in connection with the segmentation process 10 described above.

The source image file 34S and labeled image file 34L of each pair of training image files 34 are based on images of the same training subject (e.g., the same individual). In embodiments, one or more of the pairs of training image files 34 includes a source image file 34S produced by a relatively low contrast resolution clinical imaging system such as a 1.5 T and/or 3 T MRI scanner, and an associated labeled image file 34L in which the labeled structures of interest were identified and segmented in an image of the same training subject produced by a higher contrast resolution imaging system such as a 7 T scanner. Optimization of the trained deep learning model 18 during the training method 30, and the ability of the trained deep learning model to accurately segment (e.g., identify or predict) the SOI 14S in the clinical image 14, may be enhanced by the use of these pairs of training image files 34 including a source image 34S produced by a relatively low contrast resolution imaging system and an associated ground truth or labeled image file 34L produced by a relatively high contrast resolution imaging system.

### Training Image File Generation

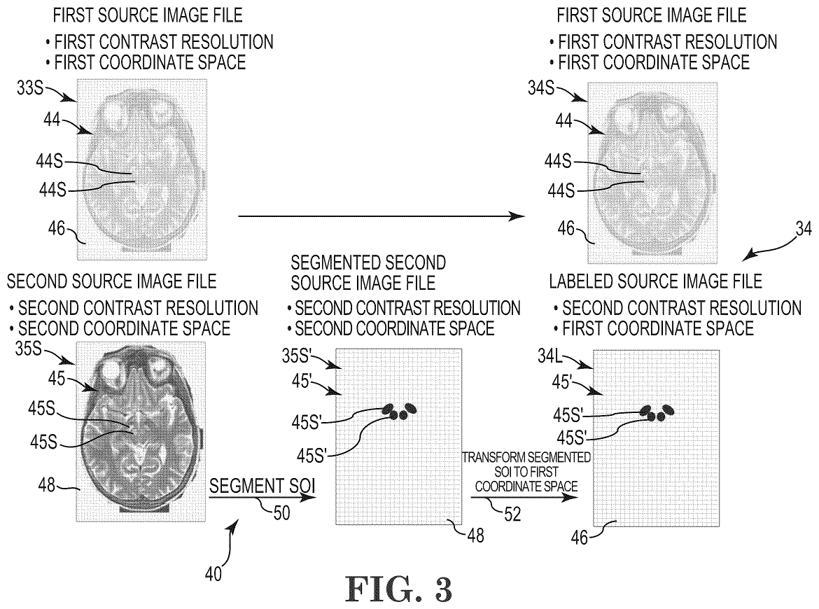

FIG. 3 is a diagrammatic illustration of a method 40 by which pairs of training image files 34 can be generated, in accordance with embodiments. As shown, method 40 uses a first source image file 33S of a training subject that is produced on a first or relatively low contrast resolution imaging system such as a 1.5 T or 3 T MRI scanner (not shown), and a second or relatively high contrast resolution source image file 35S of the same training subject that is produced on a second or relatively high contrast resolution imaging system such as a 7 T MRI scanner (not shown). The source image file 33S includes data representative of an image 44 of the training subject, including the SOI 44S. Similarly, the high contrast resolution source image file 35S includes data representative of an image 45, including SOI 45S corresponding to the SOI 44S in the first source image file 33S. Briefly, and as described in greater detail below, the first source image file 33S may be used as the source image file 34S of a pair of training images files 34, and the second source image file 35S is processed for use as the labeled image file 34L of the pair of training image files 34.

As shown diagrammatically in FIG. 3, the first source image file 33S is defined by a first coordinate system or space 46 (depicted as a grid of a cartesian coordinate space for purposes of example, but which is a three-dimensional space in embodiments). The image 44 represented by the source image file 33S, including the SOI 44S, are defined in the first coordinate space 46. For example, each voxel representing a portion of the image 44 (not separately shown), may be defined by a location in the first coordinate space 46. Similarly, the image 45 represented by the second source image file 35S, including the SOI 45S, is defined in a second coordinate system or space 48 (also depicted as a grid of a cartesian coordinate space for purposes of example). For example, each voxel representing a portion of the image 45 (not separately shown), may be defined by a location in the second coordinate space 48. In embodiments, coordinate spaces 46 and 48 may be different coordinate spaces. For example, the different imaging systems used to produce the source image files 33S and 35S may be configured with different coordinate spaces. In embodiments, coordinate spaces 46 and 48 may the same coordinate spaces. Because of any of one or more factors such as the use of different imaging systems defined by different coordinate spaces 46 and 48, or the different locations or orientations of the training subjects in an imaging system, the images 44 and 45, and associated SOI 44S and 45S defined by the source image files 33S and 35S, may be defined differently in the respective coordinate spaces 46 and 48.

A relationship between the first and second coordinate spaces 46 and 48 is known and defined by coordinate system relationship information. Using the coordinate system relationship information, locations of each of one or more voxels or portions of voxels in the coordinate space 46 or 48 of one of the source image files 33S or 35S can be transformed or mapped to a corresponding location of one or more voxels or portions of voxels in the coordinate space 46 or 48 of the other of the source image files 33S or 35S.

As shown in FIG. 3, and noted above, the first source image file 33S becomes or may be used as the source image file 34S of the pair of training images 34. The SOI 45S in the second source image file 35S are segmented by a segmentation process 50 to produce a segmented second source image file 35S′ including the segmented SOI 45S′. In connection with the segmentation process 50, segmentation may refer to the tracing of the anatomy of the training subject as represented by the image 45 to define specific SOI. The segmented SOI 45S′ are defined in the second coordinate space 48 in the segmented second source image file 35S′. In the illustrated embodiments, the segmented second source image file 35S′ is a binary image mask file substantially consisting only of the segmented SOI 45S′. In other embodiments (not shown) the segmented second source image file 35S′ may include at least some additional portions of the image 45.

In embodiments, the segmentation process 50 is performed manually by neuroanatomy experts using computer visualization tools displaying the image 45 based on the second source image file 35S. Commercially available computer visualization tools such as Avizo, Amira or 3DSlicer may be used in connection with the segmentation process 50, for example. In embodiments, for example, a group of one or more (e.g., five) neuroanatomy experts of the basil ganglia such as neurosurgeons, neurologists and/or neuroimaging experts reviewed the relatively high contrast resolution (e.g., 7 T) images 45 of the second source image file 35S and determined the anatomical borders of each of the left and right portions of the STN, the left and right portions of the GPi, the left and right portions of the GPe, and/or other SOI such as the RN and SN (e.g., defining in what image (slice number) the SOI starts and ends in axial, coronal and sagittal views). The group of experts determined by consensus the final borders of the structures. Consensus concerning the locations and borders of the SOI was determined by mutual agreement of experts in the field of basil ganglia anatomy, physiology, neurosurgery, neurology and imaging in embodiments. The criteria for determining the locations of SOI such as the STN included prior anatomical studies that determine its location relative to other adjacent structures such as the SN, RN and thalamus, for example. Borders may be determined based on image contrast relative to that of the SOI and other structures, as well as nearby fiber pathways (e.g., internal capsule and Fields of Forel). In embodiments, the segmented second image file 35S′ may be labeled to identify each segmented SOI 45S′ with a unique class label identifier (e.g., 1 and 2 for the left and right hemisphere portions of the STN, 3 and 4 for the left and right portions of the RN, 5 and 6 for the left and right portions of the SN, 7 and 8 for the left and right portions of the GPi, and 9 and 10 for the left and right portions of the GPe, respectively). The segmented second source image file 35S′ may be labeled to identify portions of the image 45′ that do not correspond to a SOI 45S′ with a unique identifier such as 0.

As shown in FIG. 3, the segmented SOI 45S′ in the segmented second source image file 35S′ are translated or defined into the first coordinate space 46 of the first source image file 33S by a transformation process 52 to produce a the labeled source image file such as 34L. In connection with the transformation process 52, transformation refers to the process of bringing the segmented image 45′ (e.g., the segmented SOI 45S′) and the source image 44 into a common coordinate space. In embodiments, the transformation process 52 is performed using commercially or otherwise publicly available computer-implemented software tools such as ANTS. By the transformation process 52, the segmented SOI 45S′ are effectively translated or mapped from their voxels in the second coordinate space 48 into associated voxels in the first coordinate space 46 using the relationship (e.g., a registration relationship) information defining the relationship between the first coordinate space 46 and the second coordinate space 48. Following transformation process 52, the segmented SOI 45S′ are effectively located in the same space in the first coordinate space 46 as the SOI 44S of the image 44 (e.g., the segmented SOI 45S′ are effectively located in the image 44 of the first source image file 33S at the same dimension, the same orientation and/or the same location that the SOI 44S had in the image 44, but at the higher contrast resolution of the segmented image 45′). In embodiments, transformation process 52 includes affine transformation. The registration process may include one or more of translating, rotating, scaling and shearing. In embodiments, the transformation process 52 results in definition of the segmented SOI 45S′ into the labeled source image file 34L to an accuracy of less than or equal to about 1 mm. In these and other embodiments the transformation process 52 results in definition of the segmented SOI 45S′ into the labeled source image file 34L to an accuracy of less than or equal to about one voxel.

In embodiments, the training image file generation method 40 is performed separately on the source image files such as 33S and 35S to generate the pairs of training image files such as 34 for each of the STN and the GP (e.g., including both the GPi and GPe). Such pairs of training image files 34 may then be used by the training method 30 (FIG. 2) to train deep learning models such as 18 optimized for segmentation of the STN, GPi and/or GPe. In embodiments, the pairs of training image files 34 may be used to separately train deep learning models optimized for segmentation of the STN, and to train deep learning models optimized for segmentation of the GPi and GPe. First and second source image files 33S and 35S of different individual training subjects may also be used to generate the pairs training image files 34 used to train deep learning models 18 for STN segmentation and deep learning models 18 for GP segmentation. As described in greater detail below, the plurality of pairs of training image files 34 produced using images of a plurality of individual training subjects may enhance the trained deep learning models 18 trained by those pairs of training image files.

FIGS. 4A and 4B diagrammatically illustrate of a region of interest (ROI) segmentation method 60 that may be used in connection with the segmentation process 50 (FIG. 3), in embodiments. FIGS. 4A and 4B illustrate embodiments of the ROI segmentation method 60 in connection with second source image file 35S for purposes of example. By the ROI segmentation method 60, a region of interest or ROI 62 in the image 45 represented by the second source image file 35S is identified and segmented. As shown, the ROI 62 includes the SOI 45S, but is smaller in size than the image 45. Segmentation process 50 described above in connection with FIG. 3 may then be performed on the ROI 62 portions of the source image file 35S (e.g., as opposed to being performed on a larger portion or the entire source image file 35S). By identifying the ROI 62 of the image 45 including the SOI 45S, and subsequently performing the segmentation process 50 on the ROI 62 cropped from the image 45, computing resources may be used more efficiently during the segmentation process 50.

ROI segmentation method 60 may be performed, for example, using conventional or otherwise known image processing and/or software tools of the types described above. In embodiments, ROI segmentation method 50 makes use of a certain or particular SOI 45S, referred to herein as the target SOI 45S_{T}, of a group of the SOI 45S in the image 45 (e.g., a subset of the SOI 45S). In embodiments, the target SOI 45S_{T} may be selected based on factors such as its ability to be relatively easily and/or accurately identified by automated image processing and software tools, and/or that has generally known positional relationships and locations to the other SOI 45S to be segmented from the image 45. For example, in connection with embodiments of the types described herein for segmenting SOI 45S such as the STN, SN, RN, GPi and GPe, the RN (red nucleus) may be selected as the target SOI 45S_{T}. The other SOI 45S, such as the STN, SN, GPi and GPe may be expected to be within a certain predetermined distance of the RN, for example based on known brain physiology.

As shown in FIG. 4A, the left and right hemisphere portions SOI 45S_{TL} and SOI 45S_{TR}, respectively, of the RN target SOI 45S_{T} are segmented or identified in the image 45. A location of each of the target SOI portions SOI 45S_{TL} and SOI 45S_{TR} is identified. In the illustrated embodiments, the center of mass (COM) 64 for each of the SOI 45S_{TL} and SOI 45S_{TR} (e.g., COM 64L and COM 64R) is segmented or identified. A line 66 extending through the COM 64L and COM 64R is defined. A center 68 of the line 66 is determined. The center 68 of the line 66 may be used to define the ROI 62. In the embodiments shown in FIG. 4B, for example, the ROI 62 is defined as a sphere of predetermined size (e.g., having a radius of a predetermined distance or number of voxels) surrounding the center 68. In embodiments of the segmentation process 50 for segmenting SOI 45S such as the STN and GP, for example, a spherical ROI 62 with a radius of about 32 mm may be used (e.g., a sphere having a radius of about 32 mm about the COM of the RN as a target SOI 45S_{T} can be expected to encompass the STN and GP in the image). Using the ROI 62 cropped during the segmentation process 50 (e.g., and not or substantially not using other portions of the image 45) enables the untrained deep learning model 36 to be trained at least substantially on the SOI 45S, thereby enhancing the training process and resulting in enhanced trained deep learning model 18. The ROI segmentation method 60, including for example the segmentation of the target SOI 45S_{T}, may be performed to accuracy levels less than the accuracy levels of the segmentation process 50 in embodiments.

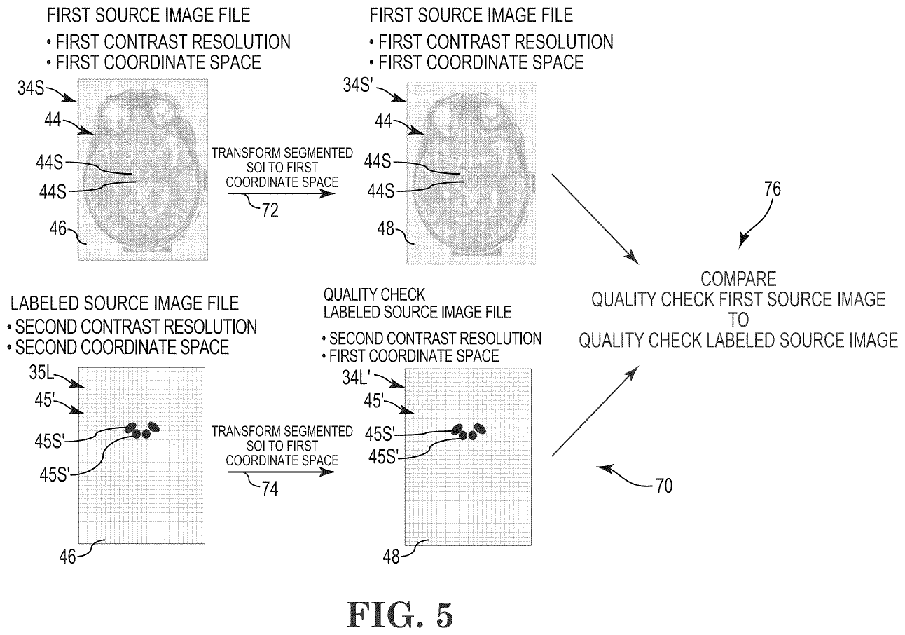

FIG. 5 illustrates steps of a ground truth quality check process 70 that may be used to assess the accuracy of labeled source image files such as 34L produced by the training image file generation method 40, in accordance with embodiments. As shown, the quality check process 70 uses the pair of training image files 34, and transforms the image 44 in the first source image file 34S and the associated image 45′ in the labeled source image file 34L, from the first coordinate space 46 into the second coordinate space 48 by processes 72 and 74, respectively. The relationship information defining the relationship between the first coordinate space 46 and the second coordinate space 48 can be used by processes 72 and 74 in a manner similar to that described above in connection with the transformation process 52. As shown by step 76, the image 44 of the quality check first source image file 34S′ and the image 45′ of the quality check labeled source image file 34L′ may then be compared to one another in the second (e.g., higher contrast resolution) coordinate space 68 to visualize whether the “ground truth” image 45′ and SOI 45S′ match the “original” image 44 and SOI 44S. By the comparison step 76, locations of other structures such as ventricles, blood vessels, gyrus and sulcus may also be compared to determine if they are in matching locations. Comparison step 76 may be performed manually and/or electronically, including with the use of conventional or otherwise known imaging, image processing and software tools such as those described above. In embodiments, quality check process 70 may be used as a final validation of the accuracy of the pairs of training image files 34 before the training image files are used in connection with the training method 30.

### Training Method

Referring back to FIG. 2, the training method 30 and trained deep learning models 18 produced by the training method may be described in greater detail. In embodiments, and as described in greater detail below, the generation of segmented clinical image files such as 20 by the segmentation method 10 (FIG. 1) make use of a plurality of trained deep learning models 18. The plurality of trained deep learning models used to produce a segmented clinical image file such as 20 may include two or more different types of deep learning models 18, and each such different type of deep learning model 18 may be trained using different pairs of training image files 34. Each of the plurality of trained deep learning models 18 is therefore unique with respect to others of the deep learning models.

Convolutional neural network (CNN) models are used as deep learning models 18 in embodiments. Types of untrained CNN deep learning models 36 used to produce the trained deep learning models 18 include Nested-UNet architectures and Fully Convolutional DenseNet (DenseFCNet) architectures in embodiments. Alternative and/or additional untrained deep learning models 36 are used in other embodiments. Versions of untrained deep learning models 36 are commercially or otherwise publicly available. Embodiments of method 10, for example, may use as untrained deep learning models 36 a Nested-UNet architecture based on code https://arxiv.org/abs/1807.10165 available at https://github.com/4uiiurz1/pytorch-nested-unet/blob/master.archs.pv, and a DenseFCNet architecture described in the Khened, Kollerathu and Krishnamurthi article entitled “Fully convolutional multi-scale residual DenseNets for cardiac segmentation and automated cardiac diagnosis using ensemble of classifiers,” in the publication Medical Image Analysis, 51 (2019) 21-45 and available at https://doi.org/10.1016/j.media.2018.10.004. The base architectures may include conventional or otherwise known substitutions and/or additions for purposes of experimentation. Examples of such substitutions and/or additions include additional linear downsampling and upsampling layers to enable acceptance of 0.5 mm isotropic inputs and to produce 0.5 mm isotropic outputs while operating internally at 1.0 mm isotropic, replacing transposed convolutions with simple linear upsampling and ELU (exponential linear unit) activation functions prior to a final softmax layer. Such substitutions and/or additions may, for example, minimize memory consumption during the training method 30. By way of example, Nested-UNet untrained deep learning models 36 of these types may have about 1.6 M parameters, and DenseFCNet untrained deep learning models of these types may have about 800K parameters.

Training process 32, which can be performed by conventional or otherwise known processes, produces the trained deep learning models 18 by passing the pairs of training image files such as 34₁-34_{N} through the mathematical operations defined by the large number of parameters of the associated untrained deep learning models 36. Good values for the parameters, e.g., values that enable the trained deep learning models 18 to produce desired outputs that accurately segment SOIs, are determined by the training process 32. Random values are initially assigned to the parameters, and those values are adjusted during the iterative process 38 to move them closer toward the good values. The differences between the actual and desired outputs of the partially trained deep learning models during the iterative process 38 are defined by values referred to as losses. During the training process 32 the losses are calculated using a mathematical loss function. In embodiments, training process 32 uses a Sorenson-Dice coefficient (DC)-based loss function. For example, by this approach, similarity between the segmentations produced by partially-trained iterations of the untrained deep learning models 36 and the ground truth images (e.g., the labeled source images such as 45′) are determined. The loss may, for example, be calculated as an average of 1-DC for each SOI, since the loss may be minimized. In embodiments, weighted averages may be used to emphasize the relative importance or difficulty of certain SOI.

Individual iterations or passes of the iterative process 38 may be referred to as epochs. Each epoch may iterate though all image files 34₁-34_{N} of each set of training image files 34. The training image files 34 may be processed in batches of N pairs of image files 34₁-34_{N}. In embodiments, N may be 1, 2, 4 or 8. Other embodiments of training method 30 use pairs of training image files 34 having other numbers of pairs of training image files. The data of the pairs of training image files 34 may be augmented by various transformations before being applied to the deep learning model during each of one or more epochs of the iterative process 38. Examples of such augmentation transformations that may be used during the iterative process 38 include the transformations described in Table 1 below. One or more of the transformations in Table 1 may be used in embodiments.

TABLE 1

| Augmentation | |
|---|---|
| Transformation | Description |
| Random_Crop | Crop random part of the image using pitch, yaw and roll of e.g., ±15° |
| Add_Noise | Add Gaussian noise to the (intensity-normalized) image with e.g., mean |
| | 0 and standard deviation 0.02. The resulting image is renormalized |
| Tweak_Histogram | Adjust image contrast, e.g., increasing contrast for low intensity voxels |
| | and decreasing contrast for higher intensity, or vice versa. Division |
| | between high and low contrast and the amount of contrast adjustment |
| | may be chosen randomly within predefined ranges |

Alternative or additional transformations are used in other embodiments. Examples may include canonical orientation, normalize intensity, resample and image to tensor transformations, and left/right flips.

Use of the transformations may enhance the ability of the deep learning model 18 to learn from a plurality of images during each epoch of the training process 32. In effect, the partially trained deep learning model is exposed to a greater variety of training images during the training process 32 by applying the transformations to the pairs of training image files 34. The transformations include rotations, contrast adjustments and simulated noise, and their use helps prevent the training process 32 from “memorizing” the training inputs and enhances the generality of deep learning models 18 trained by the training process 32.

Embodiments of training method 30 use pairs of validation images (not separately shown) to assess the level of optimization of each iteration or partially-trained deep learning model during the training process 32. Each validation image set may include a source image file and a labeled image file similar to those of the source image file 34S and labeled image file 34L, respectively, of a training image pair 34. The labeled image file of each validation image set may be produced by a method substantially the same as or similar to the method 40 by which the labeled image file 34L of the pairs of training image files 34 are generated. In embodiments, the validation image pairs are produced using images of one or more individual subjects that are different than the one or more individual subjects associated with the pairs of training image files 34 used during the training method 30 of the associated trained deep learning model 18.

By way of example, seventy-five to two hundred epochs may be used during the training process 32 to produce deep learning models 18. As described above, during these epochs the deep learning model is optimized on the pairs of training image files 34, reducing the loss function by adjusting its parameters toward lower loss, epoch by epoch. In embodiments, to avoid overfitting the deep learning model to the pair of training images, the quality or validity of the partially-trained deep learning models is assessed by applying the partially-trained deep learning models to the source image file of each of one or more pairs of validation images, and comparing the resulting segmented validation image to the labeled image of the associated labeled image file. Segmentation processes that are substantially the same as or similar to those of the segmentation process 10 described above can be used during these quality or validity assessments (e.g., on images not seen by the deep learning model during the training process 32). In embodiments, the determination that the deep learning model is optimized by the training process 32 (e.g., during the iterative process 38 shown in FIG. 2) is made when the loss was improving on the pair of training image files 34 but not on the one or more pairs of validation images, indicating that further training is not generalizable, and that the deep learning model was optimizing its parameters at least substantially for the set of training image files.

The training method 30 described above in connection with FIG. 2 uses one or more pairs of training image files 34 produced by the segmentation method 40 described above in connection with FIG. 3. As described above, those training image files 34 may include a first source image file 34S that was generated by an imaging system defined by a first, e.g., relatively low contrast resolution, and an associated labeled source image file 34L that was produced by processing a second source image file 35S generated by an imaging system defined by a second, e.g., relatively high contrast resolution. Embodiments of training method 30 additionally or alternatively may make use of pairs of training image files having different characteristics. In embodiments, for example, training method 30 may, in addition to the pairs of training image files 34, use pairs of training image files with associated source and labeled image files that were produced by the same, or same type of, imaging system. Such additional pairs of training image files may include, for example, a source image file produced by a relatively high contrast resolution scanner such as a 7 T MRI scanner, and an associated labeled source image file which is the same image file as the source image file, but in which the labeled SOI are segmented by SOI segmentation processes such as 50 and/or ROI segmentation processes such as 60 described above. Such additional pairs of training image files may be based on images of the same training subjects as those of the pairs of training image files 34. By this approach, the training process method 30 may make use of multiple pairs (e.g., two pairs) of training image files based on different images of the same training subject individual (e.g., the set of training images 34, and a set of source and labeled image files of the same subject individual generated from the same 7 T image).

### Segmentation Method

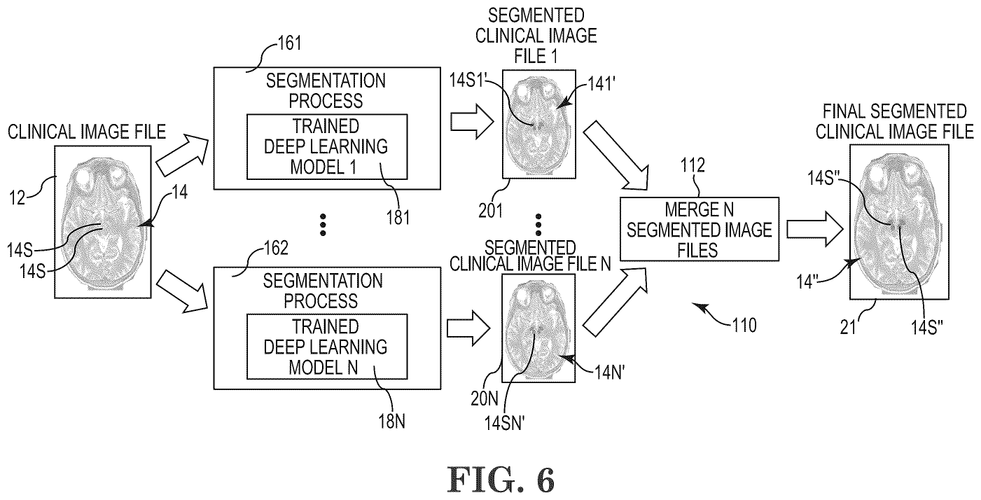

FIG. 6 illustrates a clinical image segmentation method 110 in accordance with embodiments. As shown, by segmentation method 110, a clinical image file 12 is segmented by a plurality of segmentation processes 16₁-16_{N} to produce a plurality of corresponding segmented image files 20₁-20_{N}. Each of the segmentation processes 16₁-16_{N} is performed using an associated trained deep learning model 18₁-18_{N} that is trained to segment the SOI 14S of the image 14 represented by the clinical image file 12. Each of the trained deep learning models 18₁-18_{N} is different than the others of the trained deep learning models 18₁-18_{N}. For example, one or more of the trained deep learning models 18₁-18_{N} may be of one type of model, such as a Nested-UNet model, and one or more of the others of the trained deep learning models may be of a second and different type of model, such as a DenseFCNet model. Each of one or more of the plurality of trained deep learning models 18₁-18_{N} may be trained using different pairs of training images. In embodiments, each of the trained deep learning models 18₁-18_{N} may be trained by training processes that are the substantially the same as or similar to the training methods 30 described above. The pairs of training images used to train the trained deep learning models 18₁-18_{N} may be substantially the same as or similar to those described above, including but not limited to the pairs of training images 34. In embodiments, segmentation method 110 is performed using nine different trained deep learning models 18₁-18_{N}. Other embodiments use more or fewer trained deep learning models 18₁-18_{N}.

By the segmentation processes 16₁-16_{N}, the clinical image file 12 is applied to and processed by the corresponding trained deep learning model 18₁-18_{N}. Because of differences between the trained deep learning models 18₁-18_{N}, the associated segmented clinical image files 20₁-20_{N} may have different associated and labeled SOI 14S₁′-14S_{N}′ that were identified during the respective segmentation processes 16₁-16_{N}. For example, because each of the trained deep learning models 18₁-18_{N} may be of one or more of different types, trained using different pairs of training image files, the augmentation transforming and/or random initialization, each of the models may produce different outputs. By step 112, the images 14₁′-14_{N}′ of the clinical image files 20₁-20_{N} are combined or merged into a final segmented clinical image 14″ defined by a final segmented clinical image file 21. Step 112 may, for example, use a voting algorithm. Combining the results of the different models 18₁-18_{N} may retain the results on which certain (e.g., most) of the models agree (e.g., high confidence segmentation features), while discarding features that were produce by certain (e.g., a minority) of the models (e.g., low confidence segmentation features). Segmentation methods such as 110 have been demonstrated to produce high quality segmented versions of clinical images.

The final segmented clinical image file 21 may be validated or quality checked in embodiments. For example, in embodiments the SOI 14S″ may be validated based on factors such as their volume, shape and position (e.g., distances and angles between the STN/RN/SN objects and distances between GPi and GPe objects) relative to expected volumes, shapes and positions. The expected volumes, shapes and positions may, for example, be calculated in advance using ground truth data similar to the data used to train the models. In embodiments, for example, if any of the analyzed measurements relating to the predicted SOI 14S″ are over a first threshold such as three standard deviations from the expected mean values, the predicted segmented clinical image file may be flagged with a warning. If the analyzed measurements relating to the predicted SOI 14S″ are over a second threshold such as four standard deviations from the expected mean value, the predicted segmented clinical image file may be flagged as an error.

In embodiments, the segmentation method 110 may be performed on a clinical image file 12 using a first set of trained deep learning models 18₁-18_{N} trained to segment first SOI such as the STN, RN and/or SN, to produce a first segmented clinical image file 21 with the first SOI segmented. The segmentation method 110 may be performed on the same clinical image file 12 using a second set of trained deep learning models 18₁-18_{N} trained to segment second SOI such as the GPi and GPe, to produce a second segmented clinical image file 21 with the second SOI segmented. A composite final segmented clinical image file including both the segmented first and second SOI can be produced by transforming and combining the SOI of the first and second segmented clinical image files into a common image with a common coordinate space. Transformation processes of the types described above can be used in connection with the generation of such a composite final segmented clinical image file.

FIG. 8 is a diagrammatic illustration of an exemplary computer system 138 that may be used to implement the methods described herein, including segmentation methods 10 and 110, training method 30, training image generation method 40 including segmentation process 50 and transformation process 52, ROI segmentation process 60 and/or ground truth quality check process 70. The illustrated embodiments of computer system 138 comprise processing components 152, storage components 154, network interface components 156 and user interface components 158 coupled by a system network or bus 159. Processing components 152 may, for example, include central processing unit (CPU) 160 and graphics processing unit (GPU) 162. The storage components 154 may include RAM memory 164 and hard disk/SSD memory 166, and provide the storage functionality. For example, operating system software used by the processing components 152 and one or more image processing and visualization application software packages used to implement methods described herein may be stored by the storage components 154. Software programs configured with algorithms used to perform the processing may also be stored by the storage components 154. In embodiments, the network interface components may include one or more web servers 170 and one or more application programming interfaces (APIs) 172 (e.g., for coupling the computer system 138 to a network to receive the clinical image files and to transmit the segmented clinical image files). Examples of user interface components 158 include display 174, keypad 176 and graphical user interface (GUI) 178. Embodiments of computer system 138 may include other conventional or otherwise known components to implement the methods in accordance with embodiments described herein.

It is to be understood that the above description is intended to be illustrative, and not restrictive. Many other embodiments will be apparent to those of skill in the art upon reading and understanding the above description. It is contemplated that features described in association with one embodiment are optionally employed in addition or as an alternative to features described in or associated with another embodiment. The scope of the invention should, therefore, be determined with reference to the appended claims, along with the full scope of equivalents to which such claims are entitled. For example, although described in connection with certain brain SOI, embodiments may be used in connection with other brain SOI and images of other parts of a body.

1. A method for generating image file pairs usable to train deep learning models, comprising:
receiving access to a first image file of a three-dimensional body portion of a subject including structures of interest (SOI), wherein the first image file is defined by a first coordinate space and a first effective resolution such as a contrast resolution;
receiving access to a second image file of the three-dimensional body portion of the subject including the SOI, wherein the second image file is defined by a second coordinate space and a second effective resolution such as a contrast resolution that is greater than the first resolution;
segmenting the SOI in the second image file;
transforming the segmented SOI into the first coordinate space to create a third image file of the three-dimensional body portion of the subject including the SOI; and
wherein the first image file and the third image file are usable to train deep learning models for segmentation of SOI in patient images corresponding to the SOI in the first image file and the third image file.

2. The method of claim 1 wherein receiving access to the first image file includes receiving access to a first image file produced by a scanner defined by a field strength less than or equal to about three Tesla.

3. The method of claim 1 wherein receiving access to the second image file includes receiving access to a second image file produced by a scanner defined by a field strength greater than or equal to about five Tesla.

4. The method of claim 1 wherein receiving access to the second image file includes receiving access to a second image file produced by a scanner defined by a field strength greater than or equal to about seven Tesla.

5. The method of claim 1 wherein:
receiving the first image file includes receiving a first image file produced by a first scanner; and
receiving the second image file includes receiving a second image file produced by a second scanner different than the first scanner.

6. The method of claim 1 wherein the three dimensional body portion includes a head of the subject.

7. The method of claim 1 wherein the SOI includes one or more of a subthalamic nucleus, globus pallidus, red nucleus, substantia nigra, thalamus or caudate nucleus.

8. The method of claim 1 wherein segmenting the SOI in the second image includes manually segmenting the SOI.

9. The method of claim 1 wherein transforming the SOI includes affine transforming the SOI.

10. The method of claim 1 wherein transforming the SOI includes transforming the SOI to an accuracy of less than or equal to about one voxel.

11. The method of claim 1 wherein transforming the SOI includes transforming the SOI to an accuracy of less than or equal to about 1 mm.

12. The method of claim 1 wherein transforming the SOI includes electronically transforming the SOI.

13. The method of claim 1 and further including quality checking the SOI in the third image file.

14. The method of claim 13 wherein quality checking the SOI includes:
transforming the first image file into the second coordinate space to produce a fourth image file;
transforming the third image file into the second coordinate space to produce a fifth image file; and
comparing the SOI in fourth image file and the fifth image file.

15. The method of claim 14 wherein comparing SOI in the fourth image file and the fifth image file includes a manual visualization.

16. The method of claim 1 wherein segmenting the SOI comprises segmenting a region of interest including the SOI, wherein the region of interest comprises a portion of the body portion defined by the second image file.

17. A computer system operable to provide any or all of the functionality of claim 1.

18. A method for training a deep learning model, comprising:
receiving access to a plurality of pairs of training image files, wherein one or more of the pairs of training image files is optionally generated by the method of claim 1 above, and includes:
a first image file of a three dimensional body portion of a subject including structures of interest (SOI), wherein the first image file is defined by a first coordinate system and a first effective resolution; and
a second image file of the three dimensional body portion of the subject including the SOI, wherein SOI of the second image file are defined by a second effective resolution that is greater than the first resolution, and are defined to the first coordinate system; and
iteratively processing the plurality of pairs of training image files by a first deep learning model to train the first deep learning model, including producing a plurality of partially-trained iterations of the first deep learning model and a first trained segmentation deep learning model optimized for segmentation of the SOI.

19. The method of claim 18 wherein iteratively processing the plurality of pairs of training images includes iteratively processing the plurality of pairs of training set images by a neural network deep learning model, and optionally a convolutional neural network deep learning model.

20. The method of claim 18 including validating the training of the deep learning model.

21. The method of claim 20 wherein validating the training of the deep learning model includes:
receiving access to a third image file of a three dimensional body portion of a subject different that the subjects of the pairs of training image files and including the SOI, wherein the third image file is defined by a third effective resolution that is less than the second resolution;
receiving access to a fourth image file of the three dimensional body portion of the subject of the third image file and including the SOI, wherein the fourth image file is defined by a fourth effective resolution greater than the third resolution and the SOI is segmented;
processing the third image file by each of one or more of the plurality of partially-trained iterations of the first deep learning model to produce one or more associated iteration image files including the segmented SOI; and
comparing the segmented SOI in each of the one or more of the iteration image files to the segmented SOI in the fourth image file to assess a level of optimization of each of the one or more of the partially-trained iterations of the first deep learning model.

22. The method of claim 18 wherein the first image file of the set of training image files was produced by a scanner defined by a field strength less than or equal to about three Tesla.

23. The method of claim 22 wherein the second image file of the set of training image files includes SOI produced by a scanner defined by a field strength greater than or equal to about five Tesla.

24. The method of claim 22 wherein the second image file of the set of training image files includes SOI produced by a scanner defined by a field strength greater than or equal to about seven Tesla.

25. The method of claim 18 wherein:
the first image file of the set of training image files includes a first image file produced by a first scanner; and
the second image file of the set of training image files includes a second image file produced by a second scanner different than the first scanner.

26. The method of claim 18 wherein the three dimensional body portion includes a head of the subject.

27. The method of claim 18 wherein the SOI includes one or more of a subthalamic nucleus, globus pallidus, red nucleus, substantia nigra, thalamus or caudate nucleus.

28. The method of claim 18 wherein the second image file of the set of training image files includes the SOI defined to the first coordinate system to an accuracy of less than or equal to about one voxel.

29. The method of claim 18 wherein the second image file of the set of training image files includes the SOI defined to the first coordinate system to an accuracy of less than or equal to about one mm.

30. The method of claim 18 wherein the second image file of the set of training image files includes a region of interest of the body portion defined by the second image file, and wherein the region of interest includes the SOI and comprises a portion of the body portion defined by the second image file.

31. The method of claim 18 and further including augmentation transforming one or both of the first image file and the second image file of set of training image files before processing the one or both of the first image file and the second image file by the first deep learning model, optionally including one or more of a canonical orientation transformation, a normalize intensity transformation, a region of interest crop size transformation, a training crop transformation, a resample transformation, or an add noise transformation.

32. The method of claim 18 and further including iteratively processing the first image file and the second image file by one or more additional deep learning models to train each of the one or more additional deep learning models and produce one or more associated trained segmentation deep learning models optimized for segmentation of the SOI, wherein each of the one or more additional trained deep learning models is different than the first trained deep learning model and different than others of the one or more additional trained deep learning models.

33. A computer system operable to provide any or all of the functionality of claim 18.

34.-40. (canceled)
